(19) United States
(12) Patent Application Publication
(10) Pub. No.: US 2024/0290911 A1
(43) Pub. Date: Aug. 29, 2024

(54) COVER GLASS AND DISPLAY DEVICE

(71) Applicant: Japan Display Inc., Tokyo (JP)

(72) Inventors: Yoichi KAMIJO, Tokyo (JP); Yoshikatsu IMAZEKI, Tokyo (JP); Shuichi OSAWA, Tokyo (JP); Koichi MIYASAKA, Tokyo (JP); Yoshifumi KAMEI, Tokyo (JP)

(73) Assignee: Japan Display Inc., Tokyo (JP)

(21) Appl. No.: 18/658,126

(22) Filed: May 8, 2024

Related U.S. Application Data
(63) Continuation of application No. PCT/JP2022/038600, filed on Oct. 17, 2022.

(30) Foreign Application Priority Data
Dec. 22, 2021 (JP) 2021-208580

(51) Int. Cl. H01L 33/10; H01L 25/075; H01L 27/15

(52) U.S. Cl. CPC H01L 33/10; H01L 25/0753; H01L 27/156

(57) ABSTRACT

The display device has a cover glass having a plurality of through holes and a plurality of light emitting diodes, wherein an inner surface of the plurality of through holes is covered with a reflective layer and the plurality of light emitting diodes are arranged in the plurality of through holes in a plan view. The cover glass has a first plane and a second plane located on the opposite side of the first plane, the plurality of through holes has a first through hole, the first through hole includes a first opening in the first plane and a second opening in the second plane, the width of the first opening may be narrower than the width of the second opening in an end view through the center of the first opening and the second opening.

### CROSS-REFERENCE TO RELATED APPLICATIONS

This application is a Continuation of International Patent Application No. PCT/JP2022/038600, filed on Oct. 17, 2022, which claims the benefit of priority to Japanese Patent Application No. 2021-208580, filed on Dec. 22, 2021, the entire contents of which are incorporated herein by reference.

### FIELD

One embodiment of the present invention relates to a cover glass, a display device and a manufacturing method thereof. In particular, one embodiment of the present invention relates to a display device equipped with a micro LED and a manufacturing method thereof.

### BACKGROUND

As one type of display device, LED display devices in which light emitting diodes (LED: Light Emitting Diode) are mounted are known (see JP 2021-092646).

### SUMMARY

An embodiment of the present invention is a cover glass. The cover glass includes a first plane, a second plane located on the opposite side of the first plane, a first through hole including a first opening provided on the first plane and a second opening provided on the second plane, and a reflective layer covering an inner surface of the first through-hole.

An embodiment of the present invention is a display device. The display device includes a cover glass having a plurality of through holes, and a plurality of light emitting diodes, wherein inner surfaces of the plurality of through holes are covered with a reflective layer, and the plurality of light emitting diodes are arranged in the plurality of through holes in a plan view.

### BRIEF DESCRIPTION OF DRAWINGS

FIG. 1 is a schematic top view of a display device according to an embodiment of the invention.

FIG. 2 is a schematic end view of a display device according to an embodiment of the invention.

FIG. 3 is a schematic end view of a display device according to an embodiment of the invention.

FIG. 4 is a schematic end view of a display device according to an embodiment of the invention.

FIG. 5 is a schematic end view of a display device according to an embodiment of the invention.

FIG. 6 is a schematic top view of a display device according to an embodiment of the invention.

FIG. 7 is a schematic end view of a display device according to an embodiment of the invention.

FIG. 8 is a schematic end view of a display device according to an embodiment of the invention.

### DESCRIPTION OF EMBODIMENTS

One of the aims of the present invention is to provide a cover glass with a novel structure and a display device with a cover glass and LEDs. It is also one of the aims to provide a display device with high luminance. It is also one of the aims to provide a display device with high front luminance. It is also one of the aims to provide a display device with high efficiency. It is also one of the aims to provide a display device with low power consumption. It is also one of the aims to provide a thin and lightweight display device equipped with a cover glass. It is also one of the aims to simplify the manufacturing process of the display device equipped with the cover glass.

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, the expression “a structure is exposed from another structure” means a mode in which a part of the structure is not covered by the other structure and includes a mode where the part uncovered by the other structure is further covered by another structure.

In the specification and the claims, the expression “end view” indicates when the object is cut vertically and viewed from the side. An end view shall include a view of the object as viewed from the end face. A plan view is a view of the object as seen from directly above. The expression “top view” or “plan view” shall include the view when the object is viewed in a plan view.

### First Embodiment

### 1. Overall Configuration

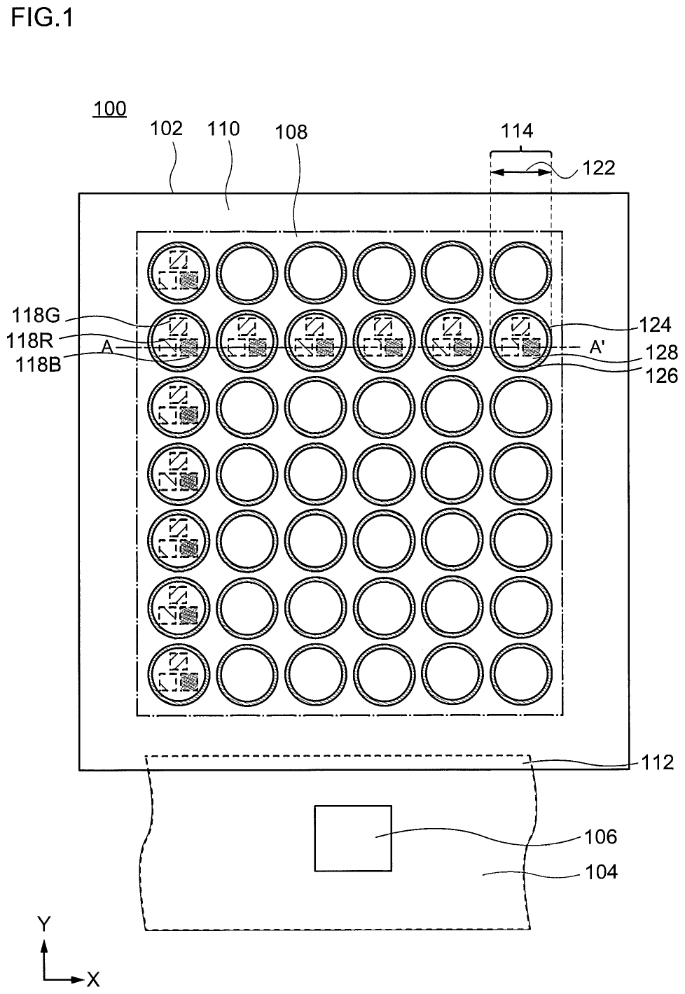

A structure of a display device 100 related to an embodiment will be described in the present embodiment. FIG. 1 is a schematic top view of a display device according to an embodiment. As shown in FIG. 1, the display device 100 has a substrate (a circuit substrate 130, described below), a cover glass 102, a flexible printed circuit substrate 104, and an IC chip 106 (Integrated Circuit chip). The display device 100 is divided into a display region 108, a peripheral region 110, and a terminal region 112.

In the display region 108, a plurality of openings 114 including a plurality of LED chips are arranged in the row direction (X-direction) and the column direction (Y-direction). The plurality of openings 114 can be arranged in a matrix-like (matrix) arrangement, as shown in FIG. 1.

The plurality of openings 114 are provided in a region corresponding to pixels of the display device 100. Within each of the plurality of openings 114, a single or plurality of LED chips are provided. The plurality of LED chips can include, for example, LED chip 118R, LED chip 118G, and LED chip 118B. As shown in FIG. 1, LED chip 118R, LED chip 118G, and LED chip 118B are located in the opening 114. The plurality of LED chips 118 can be arranged similar to the positions of the apexes of a triangle, as shown in FIG. 1, but only if they are arranged to fit within the opening 114.

When the plurality of LED chips is provided in each opening 114 as described above, the color of the light emitted by each LED chip can be red, blue, or green.

Furthermore, although not shown in the figure, the display device 100 may be provided with a single opening of a size such that the opening 114 shown in FIG. 1 and the adjacent openings are combined. In other words, although the opening 114 shown in FIG. 1 is shown as an example of an opening provided for each pixel of the display device 100, one opening may be provided for two or more pixels.

The shape of the plurality of openings 114 can be circular or oval, as shown in FIG. 1. The shape of the openings need not be a regular circle. A length 122 of the opening can represent the length of a line segment that passes through the center of the circle and has two ends on the circumference of the opening when the opening is a circle. The length 122 of the opening can be, for example, equal to or greater than 100 μm and less than or equal to 120 μm.

The plurality of openings 114 can be the openings of the plurality of through holes 124 in the cover glass 102, as shown in FIG. 1. Accordingly, the plurality of LED chips in the plurality of openings 114 are located in the plurality of through holes 124. Specifically, as shown in FIG. 1, an LED chip 118R, an LED chip 118G, and an LED chip 118B are disposed within the opening 114 and the through-hole 124. The LED chip 118R, LED chip 118G, and LED chip 118B arranged in this manner can be referred to as a plurality of LED chips 118. Furthermore, as mentioned above, the LED chips disposed in each opening 114 and each through-hole 124 may be a singular LED chip. For example, the LED chip 118G can be disposed in the through hole 124.

Furthermore, although not shown in the figure, the display device 100 may be provided with one through-hole of a size such that the through-hole 124 shown in FIG. 1 and the adjacent through-holes are combined. In other words, although the through hole 124 shown in FIG. 1 is an example of a through hole provided for each pixel, one through hole may be provided for two or more pixels. Thus, two or more LED chips 118R, two or more LED chips 118G, and two or more LED chips 118B may be provided in one through hole 124.

A reflective layer 126 is disposed on the inner surface of the plurality of openings 114, as shown in FIG. 1. In addition, a resin layer 128 is disposed on the inner side of the plurality of openings 114, as shown in FIG. 1.

The peripheral region 110 is a region surrounding the display region 108. Although not shown in the figure, the peripheral region 110 is a region where a driver circuit for controlling the pixel circuit in each pixel and a plurality of wirings connected from the driver circuit to the pixel circuit are provided.

The terminal region 112 is a region where a plurality of wirings connected to the driver circuitry described above are aggregated. The flexible printed circuit substrate 104 is electrically connected to the plurality of wirings in the terminal region 112. Video signals (data signals) or control signals output from an external device not shown in the figure are input to the IC chip 106 via the wiring not shown in the figure on the flexible printed circuit substrate 104. The IC chip 106 performs various signal processing on video signals and generates control signals necessary for display control. The video signals and control signals output from the IC chip 106 are input to the display device 100 via the flexible printed circuit substrate 104.

### 2. Outline Structure

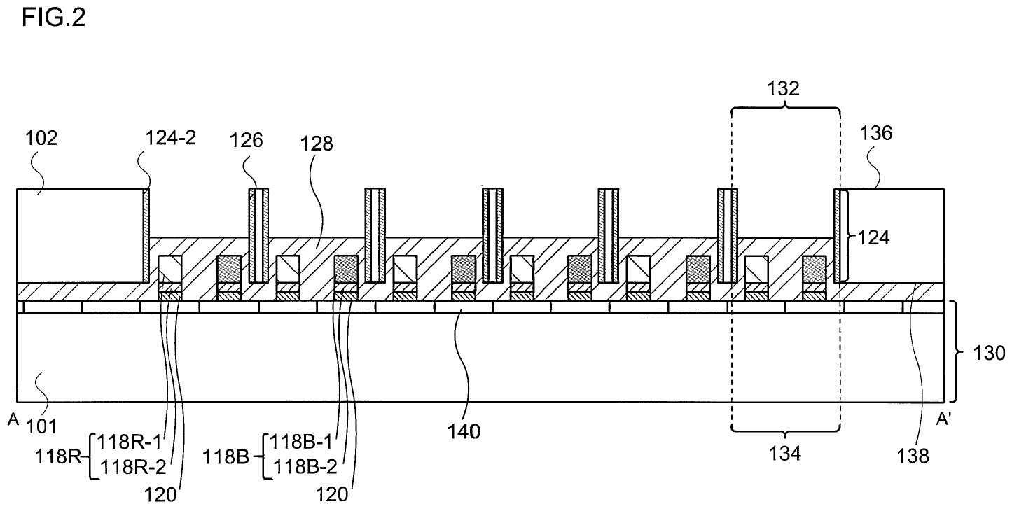

FIG. 2 shows a schematic view of the end face along the chain line A-A′ shown in FIG. 1. As shown in FIG. 2, the plurality of LED chips 118 are provided on the circuit substrate 130. As described above, a plurality of through holes 124 are provided in the cover glass 102, and the plurality of LED chips 118 are disposed inside the plurality of through holes 124.

The cover glass 102 includes a plurality of through holes 124, as described above, and the inner surface 124-2 of the plurality of through holes 124 is covered with a reflective layer 126. In this case, the emitted light of the LED chip 118 passes through the through hole 124 and is taken out of the cover glass 102. The diffused light from the emitted light of the LED chip 118 is reflected by the reflective layer 126 covering the inner surface of the through hole and is taken out of the cover glass 102.

The cover glass 102 is composed of, for example, glass or quartz. The material of the cover glass 102 should be a material that can be processed for through holes, for example, using techniques such as laser or glass etching.

The reflective layer 126 can be formed by adhering a metallic film to the surface of the cover glass 102. The reflective layer 126 is formed by removing the metallic film on the surface or back surface of the cover glass 102, and leaving the metallic film only on the inner surface of the through hole 124. If the metallic film is not removed from the surface or back surface of the cover glass 102, electrical capacitance may be formed between the cover glass 102 and the circuit substrate 130. The thickness of the reflective layer 126 can be, for example, equal to or greater than 1 μm and less than or equal to 3 μm.

The reflective layer 126 can be made of a highly reflective material. The reflective layer 126 can be made of a material with high water repellency. For example, a metal such as nickel, aluminum, etc. can be used for the reflective layer 126. The reflective layer 126 can be formed by processing a metal with high reflectivity to increase water repellency. By using a material with high reflectance for the reflective layer 126, the light diffused out of the light emitted by the LED chip 118 can be made closer to parallel light, thus increasing the light collection rate of the diffused light and improving the front luminance.

The through hole 124 includes a pair of openings. As shown in FIG. 2, the through hole 124 includes a first opening 132 and a second opening 134. The cover glass 102 includes a first plane 136 and a second plane 138 opposite the first plane 136 and facing the circuit substrate 130, the first plane 136 and the second plane 138 being on opposite sides. Accordingly, the first opening 132 of the through hole 124 can be provided on the first plane 136 and the second opening 134 of the through hole 124 can be provided on the second plane 138.

The second plane 138 of the cover glass 102 can be positioned below a semiconductor layer 118R-1, which will be discussed below. By placing the second plane 138 of the cover glass 102 below the entire semiconductor layer 118R-1, which is the light-emitting part, the reflective layer 126 can surround the semiconductor layer 118R-1 from the upper end to the lower end, and it is possible to effectively reflect the light which is diffused among the light emitted from the LED chip 118. This arrangement also allows the display device 100 to prevent light leakage in the lateral direction of the cover glass 102 or the circuit substrate 130. The display device 100 can reduce light passing through the resin layer 128, which is positioned between the cover glass 102 and the circuit substrate 130.

A resin layer 128 can be provided between the cover glass 102 and the circuit substrate 130. The resin layer 128 can be provided on the circuit substrate 130. The second plane of the cover glass 102 can be arranged on the resin layer 128. The resin layer 128 can be provided in contact with the second plane 138. The thickness of the resin layer 128 located between the second plane 138 and the circuit substrate 130 can be adjusted by the cover glass 102 and the circuit substrate 130 at the temperature and pressure during the lamination process between the cover glass 102 and the circuit substrate 130. Furthermore, the resin layer 128 may be positioned inside the through hole 124. The thickness of the resin layer 128 located inside the through hole 124 is thicker than the thickness of the resin layer 128 located between the second plane 138 and the circuit substrate 130. The resin layer 128 located inside the through hole 124 can cover the LED chip 118. This can protect the surface of the LED chip 118, ensuring insulation between the electrodes of the LED chip 118 and preventing exposure of the semiconductor surface, which will be discussed later.

The resin layer 128 can be made of a UV-curable resin, thermosetting resin, or a two-component mixed reactive resin. Resins having a refractive index similar to that of the cover glass 102 and circuit substrate 130 can be used. For example, a resin such as OCR (Optical Clear Resin) can be used. The resin layer 128 functions as an adhesive layer when the cover glass 102 and the circuit substrate 130 are bonded together. Therefore, the resin layer 128 can be an adhesive layer.

The LED chip 118R can include a semiconductor layer 118R-1. A semiconductor material made by a compound of aluminum, indium, gallium, etc. of genus III elements and nitrogen, phosphorus, arsenic, etc. of genus V elements can be used for the semiconductor layer 118R-1, for example. The material comprising the semiconductor layer 118R-1 can be used according to the emission color.

In the present example, the LED chip 118R emits red light, the LED chip 118G emits green light, and the LED chip 118B emits blue light.

The LED chip 118R can include a terminal electrode 118R-2. The terminal electrode 118R-2 functions as a terminal for electrically connecting the semiconductor layer 118R-1 and the connection electrode 120. In FIG. 2, only one terminal electrode 118R-2 and one connection electrode 120 are shown for simplicity of explanation, but two terminal electrodes 118R-2 and connection electrodes 120 can be provided for one semiconductor layer 118R-1, as in a flip chip type LED.

The terminal electrode 118R-2 functions as a terminal for electrically connecting the semiconductor layer 118R-1 to the plurality of connection electrodes 120 as mentioned above. In other words, the semiconductor layer 118R-1 can be electrically connected to the connection electrodes 120 via the terminal electrode 118R-2. In the present embodiment, the LED chip is a flip chip type LED, but in practice, two connection electrodes 120 are provided for one semiconductor layer 118R-1. Since the LED chip having the configuration described above functions as an LED, the LED chip having the configuration described above can be referred to as an LED.

The LED chip 118R can be electrically connected to the pixel circuit 140 provided on the circuit substrate 130, which will be described later, via the connection electrode 120. In other words, the semiconductor layer 118R-1 and the terminal electrode 118R-2 can be electrically connected to the pixel circuit 140 via the connection electrode 120.

An explanation of the LED chip 118R, LED chip 118G, and LED chip 118B having the same structure is omitted from the description.

The circuit substrate 130 has a region corresponding to a plurality of pixels provided in the display region 108. As described above, the plurality of through holes 124 are arranged to conform to the regions corresponding to the plurality of pixels on the circuit substrate 130. As shown in FIG. 2, the circuit substrate 130 has a pixel circuit 140 corresponding to each pixel on the circuit substrate 130, for example, to drive the LED chips 118. The support substrate 101 can be, for example, a glass substrate, a resin substrate, a ceramic substrate, or a metal substrate. Each pixel circuit 140 comprises a plurality of thin-film transistors (TFTs). Each connection electrode 120 is located in each pixel and connected to each pixel circuit 140.

In the present embodiment, an example of forming each pixel circuit 140 and each connection electrode 120 on the support substrate 101 using thin-film formation technology is shown, but the example is not limited to this example. For example, a substrate on which the pixel circuits 140 are formed on the support substrate 101 as a ready-made product from a third party (so-called active-matrix substrate) may be acquired. In this case, the connection electrode 120 can be formed on the acquired substrate. In the present embodiment, a circuit substrate 130 on which a flip chip type LED chip is mounted, for example, is described. However, the LED chip 118R is not limited to the flip chip type example with two electrodes on opposite sides of the circuit substrate 130. For example, the LED chip 118R may have a structure with an anode electrode (or cathode electrode) on the side close to the circuit substrate 130 and a cathode electrode (or anode electrode) on the side far from the circuit substrate 130. In other words, the LED chip 118R may be a face-up type LED chip having a structure with a light-emitting layer sandwiched between an anode electrode and a cathode electrode.

Although the example of 12 connection electrodes arranged on the support substrate 101 is shown in the present embodiment, at least two connection electrodes 120 are actually formed on the LED chip 118R in each pixel, since the flip chip type LED chip 118R is mounted in the present embodiment. The flip chip type LED chip has a terminal electrode connected to the n-type semiconductor and a terminal electrode connected to the p-type semiconductor. Therefore, in the present embodiment, at least two connection electrodes are arranged for each pixel in order to arrange one LED chip for each pixel. However, when the face-up type LED chip described above is used as the LED chip, only one connection electrode should be formed on the support substrate for the LED chip in each pixel.

The connection electrode 120 is composed of a conductive metallic material, for example. In the present embodiment, tin (Sn), nickel (Ni), copper (Cu), or a Sn/Ni/Cu stacked structure, etc. are used as the metallic material. However, not limited to this example, other metallic materials that can form eutectic alloys with the terminal electrode on the LED chip side, which will be described later, can be used. The thickness of the connection electrode 120 can be determined within the range of 0.2 μm to 5 μm (preferably 1 μm to 3 μm).

In the present embodiment, only one terminal electrode 118R-2 and one connection electrode 120 are drawn for simplicity of explanation, but actually, for one semiconductor layer 118R-1, two terminal electrodes 118R-2 and the connection electrode 120 are provided. However, when the face-up type LED chip described above is used as the semiconductor layer 118R-1, the structure may have one connection electrode 120 for each pixel.

3. Variation of the Resin layer

### 3-1. Variation 1

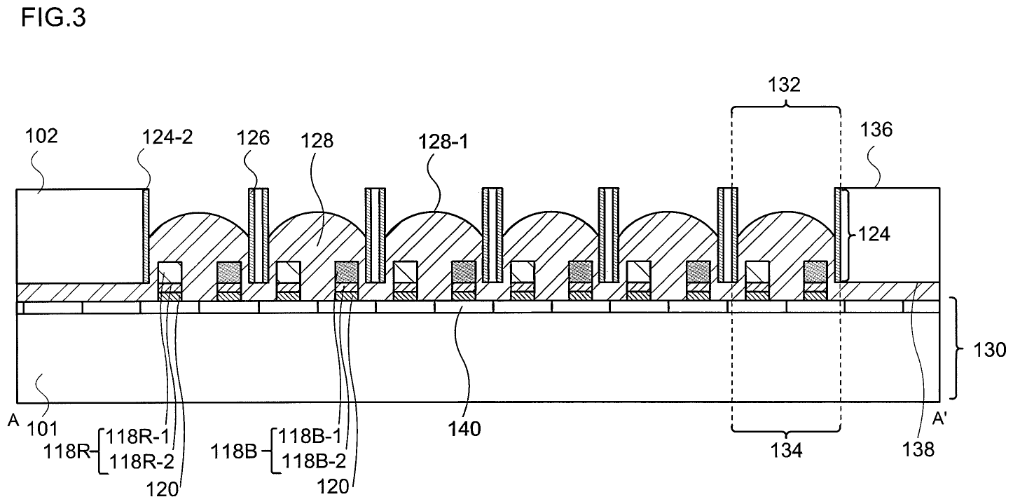

Here, a variation of the structure of the resin layer is described. FIG. 3 is a schematic end view of a display device according to the embodiment. In the display device 100, as shown in FIG. 3, the resin layer 128 located inside the through hole 124 can have a convex shape with respect to the second plane 138 of the cover glass 102. The light emitted from the LED chip 118R can reduce reflections on the outer surface of the resin layer 128 by passing through the convex-shaped portion of the resin layer 128. Also, the light emitted from the LED chip 118R can become collimated light by passing through the convex-shaped portion of the resin layer 128. In other words, this shape can increase the light collection rate of the light emitted from the LED chip 118R and further improve the frontal luminance. Therefore, the resin layer 128 located inside the through hole 124 can have a microlens effect.

An upper end 128-1 of the resin layer 128 having a convex shape can be positioned below the first plane of the cover glass 102. The position of the upper end can increase the light collection rate of the light emitted by the LED chip 118R and further improve the front luminance as the light that was not collimated out of the light emitted by the LED chip 118R is reflected by the reflective layer 126.

The convex shape of the resin layer 128 described above can be formed in the process of laminating the cover glass 102 and the circuit substrate 130 using the resin layer 128. In other words, in the above-mentioned laminating process, when the cover glass 102 is laminated on the resin layer 128 applied on the circuit substrate 130, the resin layer 128 pushed by the circuit substrate 130 and the cover glass 102, and the resin layer 128 located between the circuit substrate 130 and the through-hole 124 enter the inside of the through-hole 124, and it is possible for the resin layer 128 that has entered the through hole 124 to have a convex shape.

The convex shape of the resin layer 128 may be adjusted by the water repellency of the reflective layer material or the water repellent layer by the reflective layer processing.

### 3-2. Variation 2

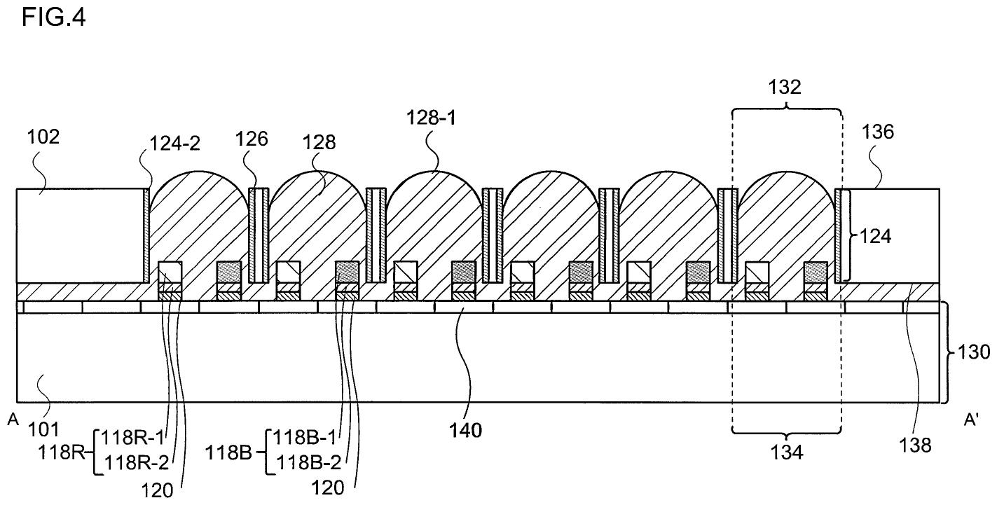

In addition, a variation of the structure of the resin layer is described. FIG. 4 is a schematic end view of a display device according to the embodiment. In the display device 100, as shown in FIG. 4, the upper end 128-1 of the resin layer 128 having a convex shape can be positioned above the first plane 136 of the cover glass 102. Thus, by adjusting the position of the upper end 128-1 of the resin layer 128 having a convex shape, the focal point from the LED chip 118 or the focal distance from the emitting surface to the resin layer 128 having a convex shape can be adjusted.

The resin layer 128 is provided inside the first opening 132. As described above, the upper end 128-1 of the resin layer 128 having a convex shape is located above the first plane 136 of the cover glass 102, but the resin layer 128 is provided inside the first opening 132 to prevent the resin layers provided inside the adjacent through-holes from touching each other.

### 4. Variation of Through-Hole

### 4-1. Variation 1

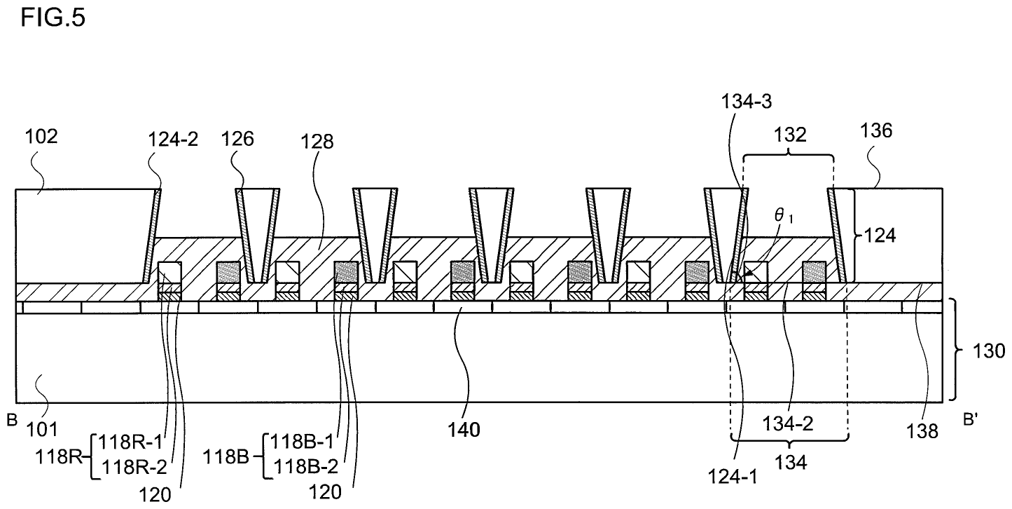

Here, a variation of the through-hole structure is described. FIG. 5 is a schematic end view of a display device according to an embodiment. In the display device 100, the through hole 124 can have openings of different sizes, as shown in FIG. 5. The through hole 124 has a pair of first openings 132 and second openings 134. The first opening 132 can be provided on the first plane 136 of the cover glass 102. The second opening 134 can be provided on the second plane 138 of the cover glass 102. The width of the first opening 132 is narrower than the width of the second opening 134, as shown in FIG. 5.

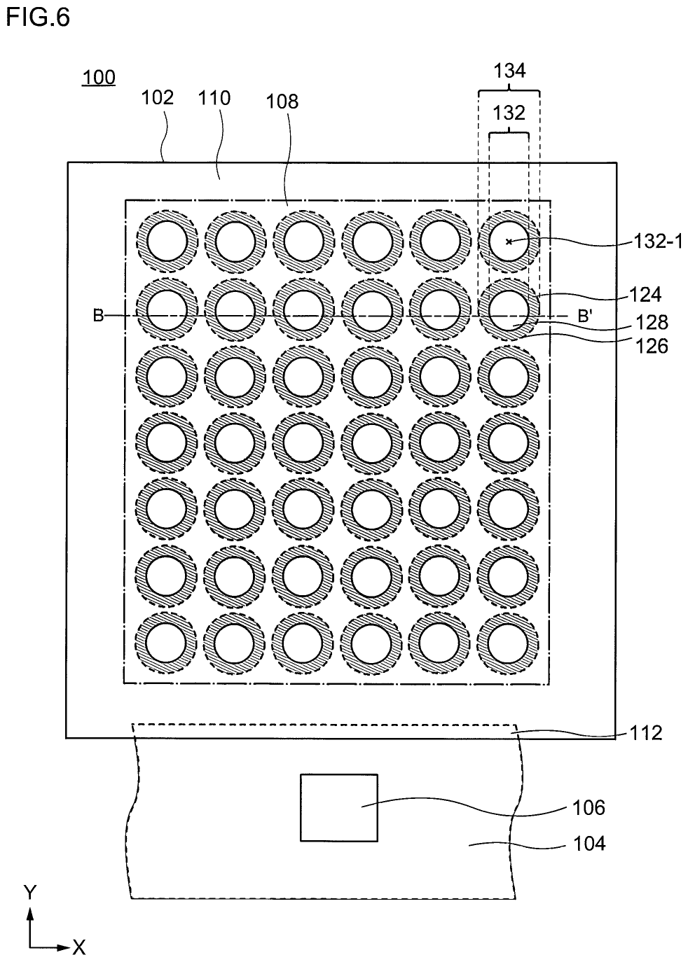

Here, the top view of FIG. 5, which is a schematic end view of the display device 100, is shown in FIG. 6. The schematic of the B-B′ cross section shown in FIG. 5 corresponds to the cross section along the chain line B-B′ shown in FIG. 6.

As shown in FIG. 6, the through hole 124 shown in FIG. 5 can be provided with a first opening 132 and a second opening 134 of different sizes. As shown in FIG. 6, the first opening 132 can be provided inside the second opening 134.

Since the first opening 132 has a circular shape, the width of the first opening 132 represents the length of a line segment that passes through the center of the first opening 132 and has two ends on the circumference of the opening. Similarly for the second opening 134, the width of the second opening can represent the length of a line segment that passes through the center of the second opening 134 and has two ends on the circumference of the opening. Thus, in the top view, the width of the first opening 132 is narrower than the width of the second opening.

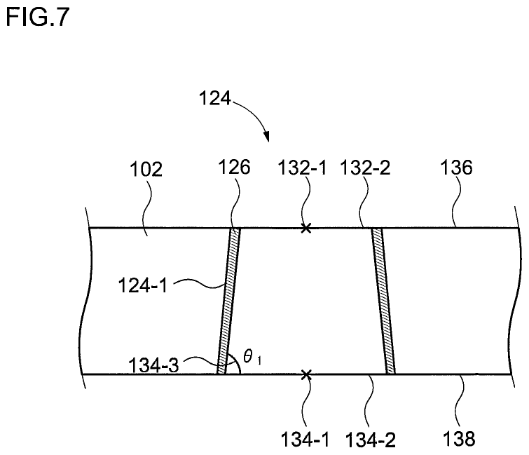

Next, a schematic end view of a part of the display device 100 including the through hole 124 shown in FIG. 5 and FIG. 6 is shown in FIG. 7.

As shown in FIG. 6, the first opening 132 of the through hole 124 is circular and therefore has a center of the first opening 132, and as shown in FIG. 7, the first opening 132 is provided through the center 132-1. The center 132-1 of the first opening 132 shown in FIG. 7 can refer to the center of the first opening 132 described above. As shown in FIG. 6, the second opening 134 of the through hole 124 is also circular and therefore has the center of the second opening 134, and as also shown in FIG. 7, the second opening 134 is similarly provided to pass through the center 134-1. The center 134-1 of the second opening 134 shown in FIG. 7 can refer to the center of the second opening 134 described above. Thus, the width of the first opening 132 described above can represent the line segment 132-2 passing through the center 132-1 of the first opening 132. Similarly, the width of the second opening 134 can represent the line segment 134-2 passing through the center 134-1 of the second opening 134. The length of line segment 132-2 through the center 132-1 of the first opening 132 in FIG. 7 corresponds to the width of the first opening in FIG. 5.

Furthermore, the through hole 124 can have a generating line 124-1. As shown in FIG. 7, the line connecting the point on the first opening 132 in the end view and the point on the second opening 134 in the end view can be the generating line 124-1. The generating line 124-1 shown in FIG. 7 corresponds to the generating line 124-1 shown in FIG. 5. The through hole 124 has a first angle θ₁ 134-3 formed by a line segment 134-2 that passes through the center 134-1 of the generating line 124-1 and the second opening 134-1, as shown in FIG. 7. The first angle θ₁ 134-3 shown in FIG. 7 corresponds to the angle formed by the generating line 124-1 and the second opening 134 shown in FIG. 5. The first angle θ₁ 134-3 can be, for example, equal to or greater than 85 degrees and less than or equal to 90 degrees.

### 4-2. Variation 2

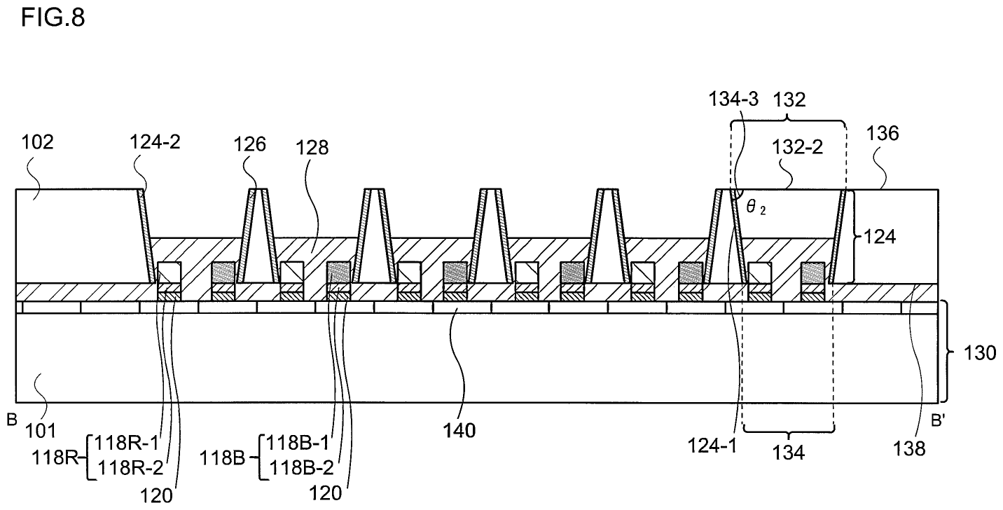

In addition, a variation of the through-hole structure is described. FIG. 8 is a schematic end view of a display device according to the embodiment. In the display device 100, the through hole 124 shown in FIG. 8 differs from the through hole 124 shown in FIG. 5 in the relationship of the sizes of the first opening 132 and the second opening 134. Specifically, as shown in FIG. 8, the width of the first opening 132 can be wider than the width of the second opening 134. In other words, the relationship between the widths of the first opening 132 and the second opening 134 of the through hole 124 shown in FIG. 5 is opposite. Therefore, as shown in FIG. 8, the second angle θ₂ 132-3 formed by the generating line 124-1 of the through hole 124 and the first opening 132 can be, for example, equal to or greater than 85 degrees and less than or equal to 90 degrees.

In addition, a second opening 134, not shown, is provided inside the first opening 132 in the top view.

In the display device 100, a cover glass 102 having a plurality of LED chips 118R, LED chips 118G, and LED chips 118B and a plurality of through holes 124 is provided on the circuit substrate 130. The inner surface 124-2 of the plurality of through holes 124 is covered by a reflective layer 126, the plurality of LED chips 118 are disposed inside the plurality of through holes 124, and the plurality of LED chips 118 have a structure in which they are surrounded by the reflective layer 126. With this structure, diffused light out of the light emitted from the plurality of LED chips 118 is emitted by the reflective layer 126 to the outside of the display device 100.

Furthermore, in the display device 100, a resin layer 128 is provided between the circuit substrate 130 having a plurality of LED chips 118 and the cover glass 102 having a plurality of through holes 124. The resin layer 128 is further provided inside the plurality of through holes 124, and the resin layer 128 covers the plurality of LED chips 118 provided inside the through holes 124. With this structure, the resin layer 128 protects the plurality of LED chips 118.

In the display device 100, the resin layer 128 provided inside the through hole 124 has a convex shape. The diffused light out of the light emitted from the plurality of LED chips 118 is emitted to the outside of the display device 100, and the display device 100 has a simple structure. Therefore, according to the embodiment, by providing a reflective layer 126 inside the through hole 124 included in the cover glass 102 in the display device 100, the luminance of the display device 100, especially the front luminance, can be improved and the power consumption can be reduced.

Furthermore, since the resin layer with a convex shape is provided in the through hole 124 included in the cover glass 102, there is no need to separately install a condenser lens on the cover glass 102, and the manufacturing process of the display device 100 can be simplified and low cost can be achieved. In addition, since no condenser lens is provided on the cover glass 102, the display device 100 can be made thinner and more lightweight.

Each embodiment described above as embodiments of the present invention can be implemented in combination as appropriate as long as they do not contradict each other. In addition, those skilled in the art could appropriately add, delete or change the design of the constituent elements based on the display device of each embodiment, or add, omit or change conditions as long as it does not depart from the concept of the present invention and such changes are included within the scope of the present invention.

Even if other actions and effects different from the actions and effects brought about by the aspects of each embodiment described above are obvious from the description of the present specification or those which could be easily predicted by those skilled in the art, such actions and effects are to be interpreted as being provided by the present invention.

What is claimed is:

1. A cover glass comprising:
a first plane;
a second plane located on the opposite side of the first plane;
a first through hole including a first opening provided on the first plane and a second opening provided on the second plane; and
a reflective layer covering an inner surface of the first through-hole.

2. The cover glass according to claim 1, wherein a first angle formed by the second opening and a generating line of the first through hole in an end view through a center of the first opening and the second opening is equal to or greater than 85 and less than or equal to 90 degrees.

3. A display device comprising:
a cover glass including a plurality of through holes; and
a plurality of light emitting diodes,
wherein
inner surfaces of the plurality of through holes are covered with a reflective layer, and
the plurality of light emitting diodes are arranged in the plurality of through holes in a plan view.

4. The display device according to claim 3, further comprising a substrate,
wherein
the cover glass has a first plane and a second plane located on an opposite side of the first plane,
the second plane faces the substrate,
the plurality of through holes has a first through hole,
the first through-hole includes a first opening on the first plane and a second opening on the second plane, and
the width of the first opening is narrower than the width of the second opening in an end view cut through a plane passing through the center of the first opening and the second opening.

5. The display device according to claim 4, wherein a first angle formed by the second opening and the generating line of the first through hole in an end view cut by a plane passing through a center of the first opening and the second opening is equal to or greater than 85 degrees and less than or equal to 90 degrees.

6. The display device according to claim 3, further comprising a substrate,
wherein
the cover glass has a first plane and a second plane located on the opposite side of the first plane,
the second plane faces the substrate,
the plurality of through holes has a first through hole,
the first through-hole includes a first opening on the first plane and a second opening on the second plane, and
a width of the first opening is wider than a width of the second opening in an end view cut through a plane passing through a center of the first opening and the second opening.

7. The display device according to claim 6, wherein a second angle formed by the first opening and a generating line of the first through hole in an end view cut by a plane passing through a center of the first opening and the second opening is equal to or greater than 85 degrees and less than or equal to 90 degrees.

8. The display device according to claim 3, further comprising a resin layer located inside the plurality of through holes.

9. The display device according to claim 8,
wherein
the cover glass has a first plane and a second plane located on the opposite side of the first plane,
the plurality of through holes has a first through hole,
the first through hole includes a first opening on the first plane and a second opening on the second plane, and
the resin layer inside the first through hole has a convex shape with respect to the second opening.

10. The display device according to claim 9, wherein an upper end of the convex shape is located below the first plane in an end view through a center of the first opening and the second opening.

11. The display device according to claim 9, wherein an upper end of the convex shape is located above the first plane in an end view through the center of the first opening and the second opening.

12. The display device according to claim 8,
wherein
the cover glass has a first plane and a second plane located on the opposite side of the first plane,
the plurality of through holes has a first through hole,
the first through hole includes a first opening provided on the first plane and a second opening provided on the second plane, and
the resin layer is further provided in contact with the second plane.
